(19) United States
(12) Patent Application Publication
(10) Pub. No.: US 2026/0040553 A1
(43) Pub. Date: Feb. 5, 2026

(54) LOW RESISTANCE CONTACT AND METHOD

(71) Applicant: Micron Technology, Inc., Boise, ID (US)

(72) Inventors: Giovanni Mazzone, Villasanta, MI (US); David H. Wells, Boise, ID (US)

(21) Appl. No.: 19/278,900

(22) Filed: Jul. 24, 2025

Related U.S. Application Data
(60) Provisional application No. 63/677,649, filed on Jul. 31, 2024.

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

Apparatus and methods are disclosed, including memory devices and systems with conductive passages. Conductive passages are shown that include a plurality of dielectric portions, and a continuous conductor network, within the plurality of dielectric portions. Apparatus and methods are disclosed, including memory devices and systems with overlapping cylinders of dielectric that form isolation structures.

### PRIORITY APPLICATION

This application claims the benefit of priority to U.S. Provisional Application Ser. No. 63/677,649, filed Jul. 31, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates a top view of a conductive passage in accordance with some example embodiments.

FIG. 2B illustrates a side view of the conductive passage from FIG. 2A in accordance with some example embodiments.

FIG. 3A illustrates a top view of a stage of manufacture for a conductive passage in accordance with some example embodiments.

FIG. 3B illustrates a side view of the stage of manufacture from FIG. 3A in accordance with some example embodiments.

FIG. 4A illustrates a top view of a stage of manufacture for a conductive passage in accordance with some example embodiments.

FIG. 4B illustrates a side view of the stage of manufacture from FIG. 4A in accordance with some example embodiments.

FIG. 4C illustrates a perspective view selected components of a semiconductor device in accordance with some example embodiments.

FIG. 5A illustrates a top view of a stage of manufacture for a conductive passage in accordance with some example embodiments.

FIG. 5B illustrates a side view of the stage of manufacture from FIG. 5A in accordance with some example embodiments.

FIG. 5C illustrates an isometric view of a portion of an isolation perimeter in accordance with some example embodiments.

FIG. 6A illustrates a top view of a stage of manufacture for a conductive passage in accordance with some example embodiments.

FIG. 6B illustrates a side view of the stage of manufacture from FIG. 6A in accordance with some example embodiments.

FIG. 6C illustrates top view of a portion of a conductive passage in accordance with some example embodiments.

FIG. 7 illustrates an example method flow diagram in accordance with other example embodiments.

FIG. 8 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

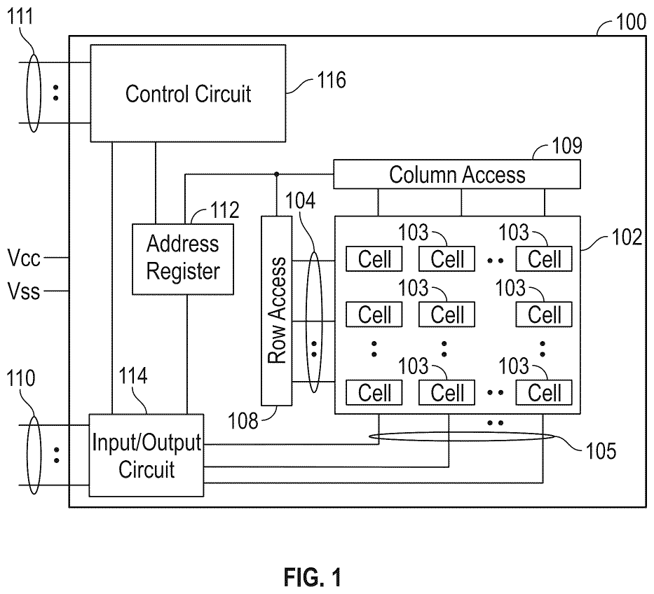

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

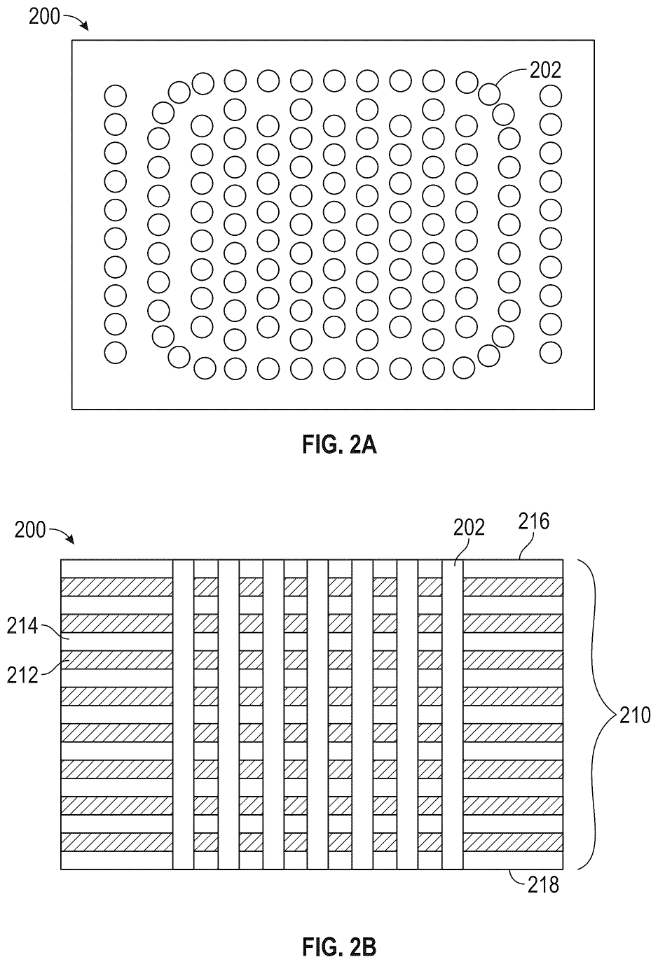

Memory cells 103 and other circuits 114, 116, etc. may include transistors and utilize methods as described in more detail in FIGS. 2A-4. In one example, memory arrays 102 include RAM storage, and peripheral circuits such as circuits 114, 116, 108, 109, etc. may include transistors as described in more detail in FIGS. 2A-4. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

In one example semiconductor device, memory strings are formed vertically using a stack of alternating dielectric and conductor layers. Selected stages of manufacture are shown in the present disclosure to form conductive passages through all or a portion of the stack of alternating dielectric and conductor layers. In selected examples, conductive passages formed as shown include a continuous conductor network, within a plurality of dielectric portions. The conductive passages shown provide high levels of conductivity, and utilize manufacturing processes that reduce complexity and cost of manufacture.

FIG. 2A shows a top view of a semiconductor device 200 including a stack 210 of alternating dielectric and conductor layers. FIG. 2B shows the stack 210 in a side view. A number of conducting layers 212 are alternated with a number of dielectric layers 214 to form the stack 210. In one example, the stack 210 is used to form a number of memory strings in a memory array. The conductor layers 212 are used to form wordlines, and the dielectric layers 214 provide electrical isolation between wordlines. In one example, the stack 210 is also used to form conductive passages formed as shown. In one example, the conductor layer 212 in FIG. 2A includes a placeholder conductor layer, such as a nitride layer or other material that is later replaced with a more conductive material such as a tungsten containing material using a replacement gate process.

In FIGS. 2A and 2B, a number of vertical passages 202 are formed through the stack 210. Although FIGS. 2A and 2B show the vertical passages 202 passing from a top side 216 to a bottom side 218 of the stack 210, the invention is not so limited. In other examples, the vertical passages 202 are formed through only a portion of the stack 210, and as a result “land” on a selected conductor layer 212.

In one example, the number of vertical passages 202 are used to form both memory strings and conductive passages as shown. By utilizing one lithographic mask and a single process to form both memory strings and conductive passages, manufacturing efficiencies are gained. Resulting structures in the memory strings and conductive passages related to the vertical passages 202 will have substantially similar dimensions. Examples of similar dimensions include, but are not limited to, diameter of vertical passages 202 and any taper in sidewalls of the vertical passages 202, etc.

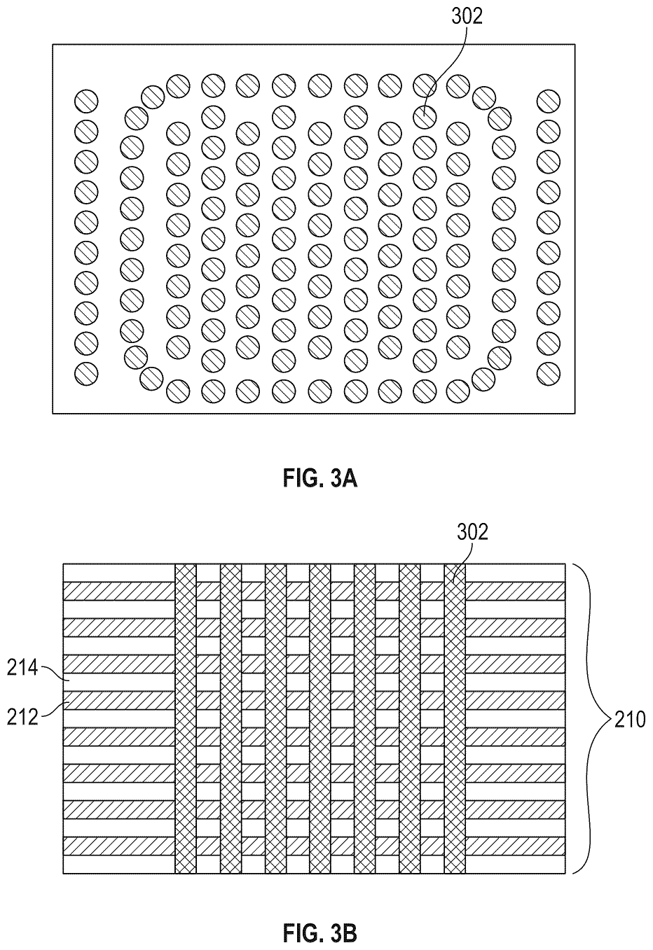

In FIGS. 3A and 3B, the number of vertical passages 202 from FIGS. 2A-2B are filled with a sacrificial material 302 as a placeholder. In one example, the sacrificial material 302 includes carbon. In one example, the sacrificial material 302 includes polysilicon. Other sacrificial materials are also within the scope of the invention.

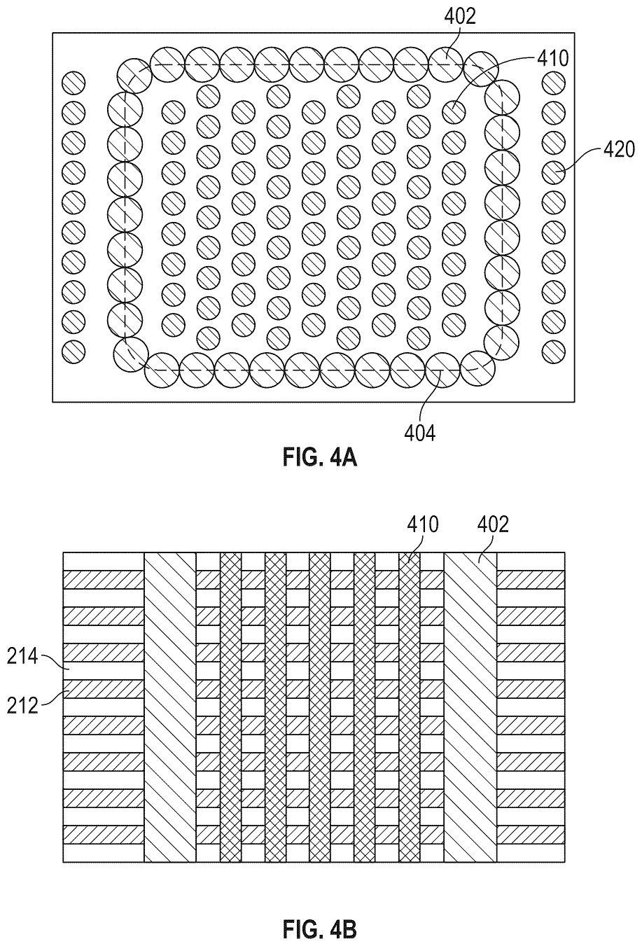

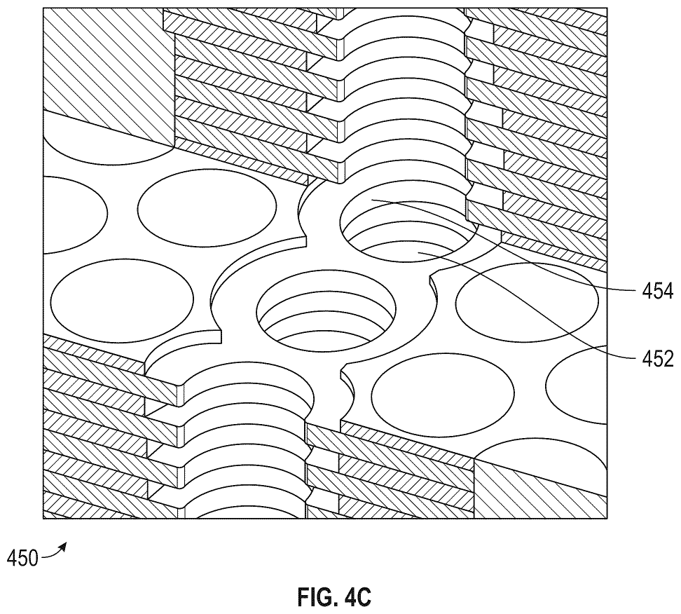

In FIGS. 4A and 4B, an isolation perimeter is formed laterally surrounding a portion of filled vertical passages in the second portion 410. The number of vertical passages 202 filled with sacrificial material 302 are defined as including a first portion 420 that are outside a perimeter 404 that are used for forming vertical memory strings. The number of vertical passages 202 filled with sacrificial material 302 are further defined as including a second portion 410 within the perimeter 404 that will be used to form a vertical conductor.

In the example of FIGS. 4A and 4B, a number of perimeter vertical passages 402 are left unmasked while other filled vertical passages in the first portion 420 and the second portion 410 are masked off. The sacrificial material is then removed from the number of perimeter vertical passages 402, and the perimeter vertical passages 402 are expanded or widened until they overlap as shown in FIG. 4A. In one example, widening includes an etch step later filled with a dielectric. In one example, the widening includes oxidation and/or conversion of conductor layers 212 to form wider silicon oxide, then subsequent filling of the perimeter vertical passages 402 with dielectric. In one example the widened perimeter vertical passages 402 include merged silicon oxide passages filled with nitride after widening. Because the perimeter vertical passages 402 are merged and formed from dielectric, the perimeter 404 is electrically isolated from surrounding structures and circuitry.

FIG. 4C shows an example structure of merged vertical passages 450. In the example of FIG. 4C, a number of finned cylinders of dielectric are shown. Cylinders 452 are shown with fins 454 arranged along a long axis of the cylinder 452. In one example, the merged vertical passages 450 are formed as a result of oxidation and/or conversion of conductor layers 212. In one example, fins 454 are detectable separately from the dielectric layers 214. In one example, fins 454 include a different dielectric material from the dielectric layers 214.

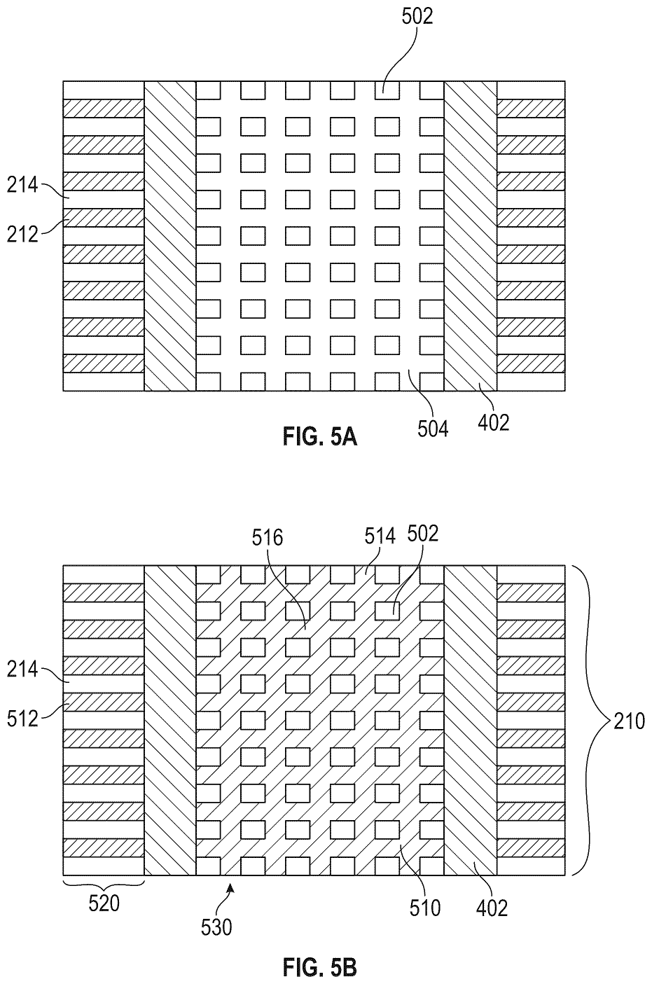

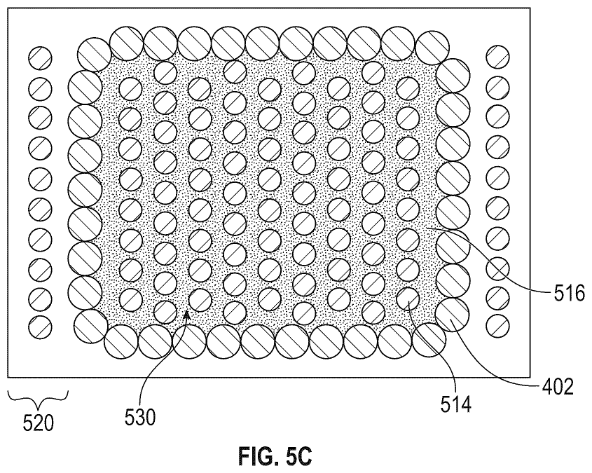

In the example of FIG. 5A, the sacrificial material 302 is removed from vertical passages 202 within the second portion 410 of FIGS. 4A and 4B. A plurality of dielectric portions 502 are left behind after removal of the sacrificial material 302. In one example, the plurality of dielectric portions 502 include dielectric layers remaining from dielectric layers 214. A number of spaces 504 remains in FIG. 5A. In the example of FIG. 5A, the number of spaces 504 are interconnected, and form a single continuous network within the dielectric portions 502.

In FIG. 5B, the number of spaces 504 are filled with a conductor 510. In one example, the conductor 510 includes tungsten. As noted above, because in one example, the number of spaces 504 form a single continuous network within the dielectric portions 502, the resulting conductor 510 forms a continuous conductor network, within the plurality of dielectric portions 502. The continuous conductor network will be detectable in contrast to structures formed from multiple components, in that the continuous conductor network does not include interfaces or seams, except where the continuous conductor network meets the plurality of dielectric portions 502. The resulting conductor 510 forms a conductive passage 530 through the stack 210 that is isolated from surrounding devices and/or circuitry by the perimeter vertical passages 402.

In one example, the conductive passage 530 includes multiple pillars 514 electrically coupled together. In one example, the conductive passage 530 includes pillars 514 and conductor layers 516 coupled together.

In one example, within an external region 520 the conductor layers 212 are also replaced with final conductor 512. In one example the replacement includes a replacement gate operation. In one example, the devices in the first portion 420 from FIG. 4A include the replacement gate final conductor 512. In one example, the replacement gate final conductor 512 is the same conductor as conductor 510, although the invention is not so limited. In one example, the replacement gate final conductor 512 is formed at the same time as the conductor 510 in the conductive passage 530.

FIG. 5C shows a top view of the conductive passage 530 isolated from surrounding devices and/or circuitry by the perimeter vertical passages 402. Vertical passages in the second portion 410 within the perimeter vertical passages 402 are filled with the conductor 510 forming multiple pillars 514 electrically coupled together. In the example shown, the multiple pillars 514 are electrically coupled together by conductor layers 516.

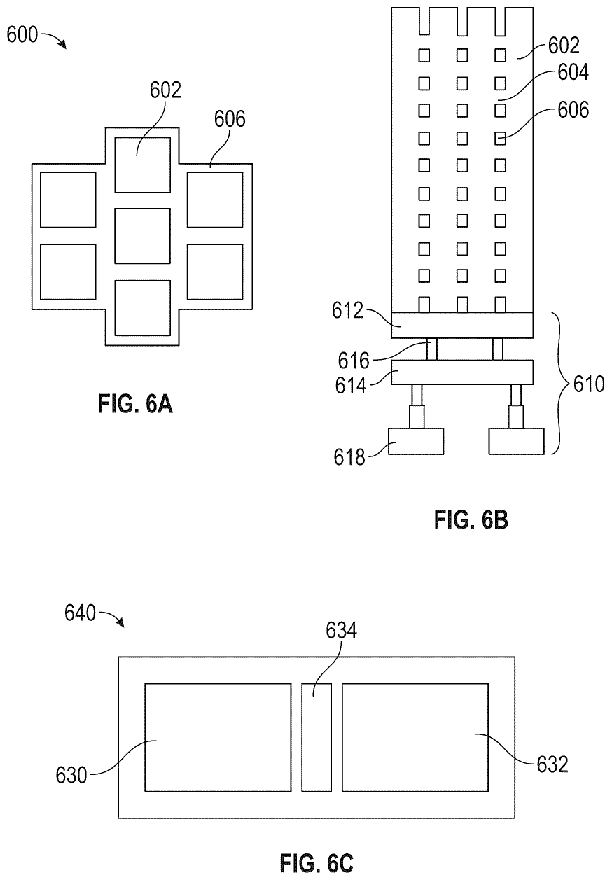

In FIG. 6A, one example arrangement of multiple pillars 602 similar to multiple pillars 514 from FIGS. 5A-5B is shown. In FIG. 6A, a honeycomb arrangement in cross section is shown. One advantage of honeycomb arrangement includes high density of pillars 602, which leads to high conductivity of a resulting conductive passage 600. FIG. 6A further shows dielectric portions 606 within the pillars 602. Other arrangements, such as orthogonal rows and columns, concentric circles, etc. are also within the scope of the invention.

FIG. 6B shows the conductive passage 600 from FIG. 6A in a side view. The pillars 602 are electrically coupled together with conductor layers 604. As discussed above, in one example the pillars 602 and layers 604 are formed concurrently and result in a continuous conductor network. The dielectric portions 606 are also shown in FIG. 6B.

The conductive passage 600 in FIG. 6B is shown coupled to subsequent metallization circuitry 610. A first layer 612, and a subsequent layer 614 are shown electrically connected by via 616. In one example, a connection pad 618 is shown on an exterior surface of a device. In one example, the connection pad 618 is located on a surface of a memory die.

FIG. 6C shows a semiconductor device 640. The semiconductor device 640 includes a first array portion 630, a second array portion 632, and a peripheral portion 634. In one example, the peripheral portion 634 includes one or more conductive passages as described in the present disclosure. As noted above, in one example, memory strings in an array portion 630, 632 include vertical structures formed in vertical cavities. In one example, the same or substantially similar verticla cavities are used to form the conductive passages in the peripheral portion 634. This provides manufacturing efficiency. Also, smaller diameter conductive passages are possible with comparable or better conductivities than previous technologies.

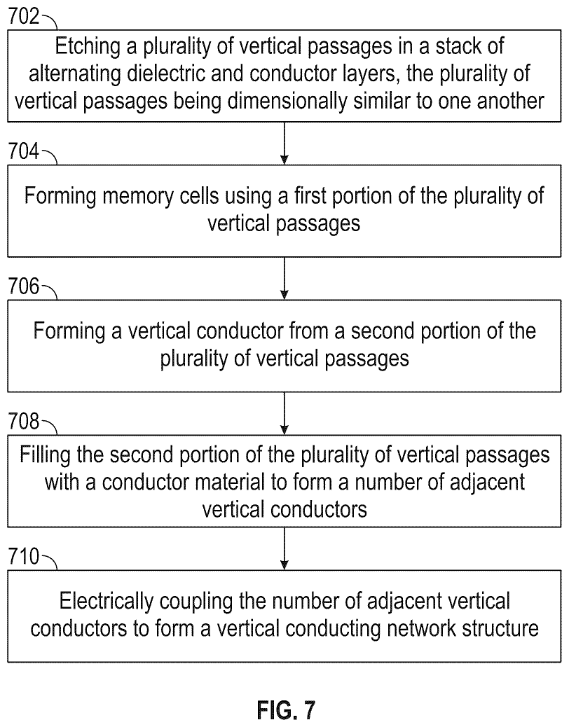

FIG. 7 shows a flow diagram of another example method of manufacture. In operation 702, a plurality of vertical passages are etched in a stack of alternating dielectric and conductor layers, the plurality of vertical passages being dimensionally similar to one another. In operation 704, memory cells are formed using a first portion of the plurality of vertical passages. In operation 706, a vertical conductor is formed from a second portion of the plurality of vertical passages. The vertical conductor is formed as shown in operation 708, which shows filling the second portion of the plurality of vertical passages with a conductor material to form a number of adjacent vertical conductors. In operation 710, the number of adjacent vertical conductors are electrically connected to form a vertical conducting network structure.

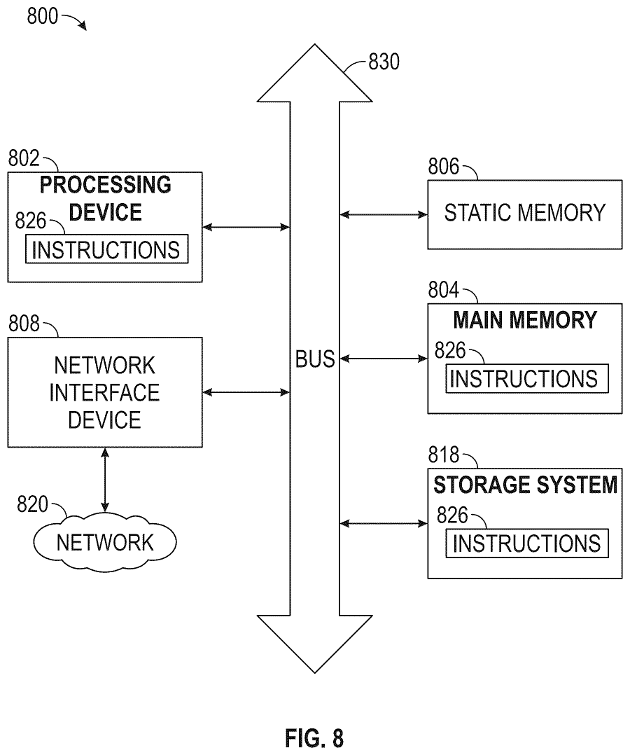

FIG. 8 illustrates a block diagram of an example machine (e.g., a host system) 800 which may include one or more vertical conductors as described above. As discussed above, machine 800 may benefit from enhanced memory performance from use of one or more of the described vertical conductors and/or memory systems, facilitating improved performance of machine 800 (as for many such machines or systems, efficient reading and writing of memory can facilitate improved performance of a processor or other components that machine, as described further below.

In alternative embodiments, the machine 800 may operate as a standalone device or may be connected (e.g., networked) to other machines. In a networked deployment, the machine 800 may operate in the capacity of a server machine, a client machine, or both in server-client network environments. In an example, the machine 800 may act as a peer machine in peer-to-peer (P2P) (or other distributed) network environment. The machine 800 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 800 may include a processing device 802 (e.g., a hardware processor, a central processing unit (CPU), a graphics processing unit (GPU), a hardware processor core, or any combination thereof, etc.), a main memory 804 (e.g., read-only memory (ROM), dynamic random-access memory (DRAM) such as synchronous DRAM (SDRAM) or Rambus DRAM (RDRAM), etc.), a static memory 806 (e.g., static random-access memory (SRAM), etc.), and a storage system 818, some or all of which may communicate with each other via a communication interface (e.g., a bus) 830. In one example, the main memory 804 includes one or more memory devices as described in examples above.

The processing device 802 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 802 can also be one or more special-purpose processing devices such as an application specific integrated circuit (ASIC), a field programmable gate array (FPGA), a digital signal processor (DSP), network processor, or the like. The processing device 802 can be configured to execute instructions 826 for performing the operations and steps discussed herein. The computer system 800 can further include a network interface device 808 to communicate over a network 820.

The storage system 818 can include a machine-readable storage medium (also known as a computer-readable medium) on which is stored one or more sets of instructions 826 or software embodying any one or more of the methodologies or functions described herein. The instructions 826 can also reside, completely or at least partially, within the main memory 804 or within the processing device 802 during execution thereof by the computer system 800, the main memory 804 and the processing device 802 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 800 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 800 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 826 (e.g., software, programs, an operating system (OS), etc.) or other data are stored on the storage system 818 can be accessed by the main memory 804 for use by the processing device 802. The main memory 804 (e.g., DRAM) is typically fast, but volatile, and thus a different type of storage than the storage system 818 (e.g., an SSD), which is suitable for long-term storage, including while in an “off” condition. The instructions 826 or data in use by a user or the machine 800 are typically loaded in the main memory 804 for use by the processing device 802. When the main memory 804 is full, virtual space from the storage system 818 can be allocated to supplement the main memory 804; however, because the storage system 818 device is typically slower than the main memory 804, and write speeds are typically at least twice as slow as read speeds, use of virtual memory can greatly reduce user experience due to storage system latency (in contrast to the main memory 804, e.g., DRAM). Further, use of the storage system 818 for virtual memory can greatly reduce the usable lifespan of the storage system 818.

The instructions 826 may further be transmitted or received over a network 820 using a transmission medium via the network interface device 808 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 808 may include one or more physical jacks (e.g., Ethernet, coaxial, or phone jacks) or one or more antennas to connect to the network 820. In an example, the network interface device 808 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 800, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Aspect 1. A memory device, comprising: a stack of alternating dielectric and conductor layers, the stack having a top side and a bottom side; an array of memory cells formed in the stack of alternating dielectric and conductor layers; a conductive passage formed through the stack of alternating dielectric and conductor layers from the top side to the bottom side, the conductive passage including: a plurality of dielectric portions; and a continuous conductor network, within the plurality of dielectric portions.

Aspect 2. The memory device of Aspect 1, wherein the plurality of dielectric portions include dielectric layers.

Aspect 3. The memory device of Aspect 1, wherein the continuous conductor network includes tungsten.

Aspect 4. The memory device of Aspect 1, wherein the array of memory cells include vertical NAND memory strings.

Aspect 5. The memory device of Aspect 1, wherein the continuous conductor network includes multiple pillars electrically coupled together.

Aspect 6. The memory device of Aspect 5, wherein the continuous conductor network includes pillars and conductor layers coupled together.

Aspect 7. The memory device of Aspect 6, wherein the pillars are arranged in a honeycomb pattern in cross section.

Aspect 8. A memory device, comprising: a stack of alternating dielectric and conductor layers, the stack having a top side and a bottom side; an array of memory cells formed in the stack of alternating dielectric and conductor layers; a conductive passage formed through the stack of alternating dielectric and conductor layers from the top side to the bottom side, the conductive passage including: a plurality of dielectric portions; a continuous conductor network, within the plurality of dielectric portions; an isolation perimeter laterally surrounding the conductive passage.

Aspect 9. The memory device of Aspect 8, wherein the isolation perimeter includes overlapping cylinders of dielectric.

Aspect 10. The memory device of Aspect 8, wherein the isolation perimeter includes overlapping finned cylinders of dielectric.

Aspect 11. The memory device of Aspect 8, wherein the conductive passage is coupled to a connection pad on a surface of a memory die.

Aspect 12. The memory device of Aspect 8, wherein the continuous conductor network includes multiple pillars electrically coupled together.

Aspect 13. The memory device of Aspect 12, wherein the array of memory cells include vertical NAND memory strings.

Aspect 14. The memory device of Aspect 13, wherein the multiple pillars are a same dimension as pillars in a memory string of the vertical NAND memory strings.

Aspect 15. The memory device of Aspect 12, wherein the multiple pillars are arranged in a honeycomb pattern in cross section.

Aspect 16. A method of forming a memory device, comprising: etching a plurality of vertical passages in a stack of alternating dielectric and conductor layers, the plurality of vertical passages being dimensionally similar to one another; forming memory cells using a first portion of the plurality of vertical passages; forming a vertical conductor from a second portion of the plurality of vertical passages, including; filling the second portion of the plurality of vertical passages with a conductor material to form a number of adjacent vertical conductors; and electrically coupling the number of adjacent vertical conductors to form a vertical conducting network structure.

Aspect 17. The method of Aspect 16, further including expanding a diameter of a third portion of the plurality of vertical passages located around the second portion of vertical passages to laterally connect the third portion of passages, and filling the third portion of passages with a dielectric to form an isolation structure.

Aspect 18. The method of Aspect 16, wherein forming the vertical conductor includes removing a first sacrificial material from the second portion of the plurality of vertical passages; removing a second sacrificial material from alternating layers in the stack; and replacing the first and second sacrificial materials with a continuous conductor material.

Aspect 19. The method of Aspect 18, wherein removing the first sacrificial material includes removing a sacrificial material chosen from a group consisting of carbon and polysilicon.

Aspect 20. The method of Aspect 19, wherein replacing the first and second sacrificial materials includes replacing with a conductor including tungsten.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device, comprising:
a stack of alternating dielectric and conductor layers, the stack having a top side and a bottom side;
an array of memory cells formed in the stack of alternating dielectric and conductor layers;
a conductive passage formed through the stack of alternating dielectric and conductor layers from the top side to the bottom side, the conductive passage including:
a plurality of dielectric portions; and
a continuous conductor network, within the plurality of dielectric portions.

2. The memory device of claim 1, wherein the plurality of dielectric portions include dielectric layers.

3. The memory device of claim 1, wherein the continuous conductor network includes tungsten.

4. The memory device of claim 1, wherein the array of memory cells include vertical NAND memory strings.

5. The memory device of claim 1, wherein the continuous conductor network includes multiple pillars electrically coupled together.

6. The memory device of claim 5, wherein the continuous conductor network includes pillars and conductor layers coupled together.

7. The memory device of claim 6, wherein the pillars are arranged in a honeycomb pattern in cross section.

8. A memory device, comprising:
a stack of alternating dielectric and conductor layers, the stack having a top side and a bottom side;
an array of memory cells formed in the stack of alternating dielectric and conductor layers;
a conductive passage formed through the stack of alternating dielectric and conductor layers from the top side to the bottom side, the conductive passage including:
a plurality of dielectric portions;
a continuous conductor network, within the plurality of dielectric portions;
an isolation perimeter laterally surrounding the conductive passage.

9. The memory device of claim 8, wherein the isolation perimeter includes overlapping cylinders of dielectric.

10. The memory device of claim 8, wherein the isolation perimeter includes overlapping finned cylinders of dielectric.

11. The memory device of claim 8, wherein the conductive passage is coupled to a connection pad on a surface of a memory die.

12. The memory device of claim 8, wherein the continuous conductor network includes multiple pillars electrically coupled together.

13. The memory device of claim 12, wherein the array of memory cells include vertical NAND memory strings.

14. The memory device of claim 13, wherein the multiple pillars are a same dimension as pillars in a memory string of the vertical NAND memory strings.

15. The memory device of claim 12, wherein the multiple pillars are arranged in a honeycomb pattern in cross section.

16. A method of forming a memory device, comprising:
etching a plurality of vertical passages in a stack of alternating dielectric and conductor layers, the plurality of vertical passages being dimensionally similar to one another;
forming memory cells using a first portion of the plurality of vertical passages;
forming a vertical conductor from a second portion of the plurality of vertical passages, including;
filling the second portion of the plurality of vertical passages with a conductor material to form a number of adjacent vertical conductors; and
electrically coupling the number of adjacent vertical conductors to form a vertical conducting network structure.

17. The method of claim 16, further including expanding a diameter of a third portion of the plurality of vertical passages located around the second portion of vertical passages to laterally connect the third portion of passages, and filling the third portion of passages with a dielectric to form an isolation structure.

18. The method of claim 16, wherein forming the vertical conductor includes removing a first sacrificial material from the second portion of the plurality of vertical passages;
removing a second sacrificial material from alternating layers in the stack; and
replacing the first and second sacrificial materials with a continuous conductor material.

19. The method of claim 18, wherein removing the first sacrificial material includes removing a sacrificial material chosen from a group consisting of carbon and polysilicon.

20. The method of claim 19, wherein replacing the first and second sacrificial materials includes replacing with a conductor including tungsten.
